(19) United States
(12) Patent Application Publication
(10) Pub. No.: US 2005/0116724 A1
(43) Pub. Date: Jun. 2, 2005

(54) Method of non-contact measuring electrical conductivity of polymer electrolyte thin films with using combined sensor

(76) Inventors: Volodymyr Red'ko, Coral Springs, FL (US); Volodymyr Khandetskyy, Dnipropetrovsk (UA); Elena Shembel, Coral Springs, FL (US); Peter Novak, Fort Lauderdale, FL (US)

Correspondence Address: AKERMAN SENTERFITT, P.O. BOX 3188, WEST PALM BEACH, FL, 33402-3188, US

(21) Appl. No.: 10/898,397

(22) Filed: Jul. 23, 2004

(30) Foreign Application Priority Data
Jul. 25, 2003 (UA) 2003007006

(51) Int. Cl. G01R 27/28; G01R 27/08

(52) U.S. Cl. 324/649; 324/691

(57) ABSTRACT

A method and integrated probe for non-contact measuring electrical conductivity of polymer electrolyte films includes placing the film on a flat dielectric substrate, exciting a probing eddy-current magnetic field using an inductance coil at a series of discrete frequencies, and measuring its impedance at these frequencies while the operating end face of the coil is located on the film surface and on the substrate.

### CROSS-REFERENCE TO RELATED APPLICATIONS

Not applicable.

### STATEMENT REGARDING FEDERALLY SPONSORED RESEARCH OR DEVELOPMENT

Not applicable.

### FIELD OF THE INVENTION

The invention relates to methods and apparatus for measurement of electrical properties of polymer electrolytes used in the production of chemical power sources.

### BACKGROUND OF THE INVENTION

Known in the art are methods and devices in which inductance coils are used as a source-of an eddy-current magnetic field and a non-contact meter of the electromagnetic properties of a material, for example, U.S. Pat. No. 4,303,885 “Multi-Frequency Eddy-Current Device and Method”, Davis, et. al., Dec. 01, 1981, G 01N 27/82; U.S. Pat. No. 5,889,401 “Method and Apparatus for Determining the Thickness of Layers Located on a Substrate”, Jourdain, et. al., Mar. 30, 1999, G 01N 27/72; U.S. Pat. No. 6,288,536 “Eddy-Current Probe”, Mandl, et. al., Sep. 11, 2001, G 01N 27/72; U.S. Pat. No. 6,479,990 “Eddy-Current Probe for an Analysis of the Object being Studied, and Method of its Operation”, Mednikov, et. al., Nov. 12, 2002, G 01N 27/72.

According to U.S. Pat. No. 4,303,885 the eddy-current method for effecting absolute and differential measuring of the parameters of discontinuities in conducting materials by using two identical probes. The magnetic field in an eddy-current probe (inductance coil) is excited at a series of frequencies. The values of the introduced coil impedance measured at these frequencies are used for determining the parameters of discontinuities and for correcting the influence of the interfering factors, such as a change of the distance between the probe and the surface of the object being controlled.

An advantage of the method is the multi-frequency operation schedule that allows obtaining more information about the object being studied.

However, the direct use of this method for controlling films of polymer electrolytes features serious problems. The surface of the samples is usually quite small making difficult the use of differential measurements. Besides, the introduced impedance of the induction coil within the range of the meter wave lengths (corresponding to the operating frequency range of the eddy-current conductance measurements of polymer electrolytes) is subject to the influence of the dielectric losses of the polymer. Hence, the conductivity being measured depends on the frequency even in such case when the conductivity of the polymer electrolyte related to the movement of the free charge carriers is frequency-independent.

U.S. Pat. No. 5,889,401 discloses a method of eddy-current testing of minimum one layer placed on a substrate. Minimum either the layer or the substrate conducts the electric current. An inductance coil is used as a primary field source or a meter of the secondary field parameters formed by the eddy currents induced in the conducting layer or substrate. The primary magnetic field is generated at least at two frequencies. The electromagnetic properties of the substrate and the layer are measured, and the obtained values of the introduced impedance are used in determining the layer properties and thickness.

An advantage of the method is the multi-frequency operating duty of the eddy-current probe and the possibility of determining the layer thickness. However, the operating and the auxiliary frequency (or frequencies) should be substantially diversified throughout the frequency range.

In the invention being applied, when measuring the electrical conductivity of the low-conducting electrolytes the upper boundary of the frequency range often reaches 2500-300 MHz while the coil practically forms a loop aerial. It is impossible to substantially increase the frequency since it is impossible to additionally reduce the probe inductance without any subsequent increase in the measurement error. The use of an auxiliary, substantially lower, frequency, for example, in the kilo-Hertz range, also requires usage of an auxiliary probe with a core spatially connected with a measuring low-turn col. This will lead to a substantial reduction of the measuring coil Q-factor due to losses of the field power in the core material whose magnetic penetrability is also frequency-dependent within the meter waves. Under such conditions the process of measuring conductance of polymer films will feature substantial errors.

U.S. Pat. No. 6,288,536 discloses an eddy-current probe having a measuring inductance coil and a measuring circuit. The inductance coil is fed with alternating current. A compensating coil is used to compensate the influence of the environmental temperature changes on the measuring coil impedance. The compensating coil, similarly to the measuring coil, is cylindrically shaped and co-axially arranged to the measuring coil.

An advantage of this invention is the use of an additional coil allowing to obtain an additional independent signal that is to compensate the interfering factor, in the given case, changes of the environmental temperature.

A disadvantage of this probe is the presence of a parasitic relationship between the fields of the measuring and compensating coils. Hence, the compensating coil signal is also dependent on the informative signal of the measuring coil that results in increasing the measurement errors.

In the U.S. Pat. No. 6,593,738 an eddy-current method is used for measuring the thickness and changing the thickness of the thin conducting coats on different structures, in particular, of metallic films on dielectric and electrical capacitance probes. The electrical capacitance probe is mechanically coupled with the inductance probe into an integral structure and is used to determine the distance to the metallic film surface. Through the use of the electrical capacitance probe signal the distance between the inductance probe and the film surface is dynamically stabilized.

An advantage of this invention is the use of an additional electrical capacitance probe coupled with the inductance probe into an integral structure and used for measuring the distance between the probe and the film surface. The use of the electrical capacitance signal allows to stabilize the distance between the inductance probe and the film surface.

However, in our case between the coplanar plates of the electrical capacitance probe and the surface of the metallic base a polymer electrolyte film is located whose properties are being studied. The dielectric permeability if the film changes as a function of the chemical composition and salt concentration in the electrolyte. Correspondingly the probe capacitance is also changed while the distance to the metallic base surface is kept constant. Therefore in our case the direct use of this patent is not reasonable due to high measurement errors.

The closest in the technical essence to the invention proposed by us is the U.S. Pat. No. 647,990 “Eddy-Current Probe for an Analysis of the Object being Studied, and method of its Operation” Mednikov, et. al.

An eddy-current probe contains a measuring and a compensating coils, as well as a measuring circuit, and serves for determining the material properties and geometric parameters of the object being studied. The probe operating method includes placing the object at a specified distance from the measuring and the compensating coils, measuring the impedance of the measuring coil at the first and the second specified frequencies, determining the material properties, as well as the object geometric parameters on the basis of the measured impedance values while compensating the temperature influence on the measuring coil by means of the signal being formed by the compensating coil. The compensating probe is spatially less than the measuring coil and is located inside of the latter, while the turns of the both coils are co-axial and their geometry is identical. The compensating probe is arranged so that it is minimally influenced by the object being studied. The temperature compensation is effected by subtracting the integral impedance of the compensating coil from the integral impedance of the measuring coil. For determining the material properties, as well as the geometric parameters of the object the latter is initially arranged at such a distance from the measuring coil that exceeds its diameter while the own impedance of the measuring coil is being determined. Then the object is brought nearer to the measuring coil and its impedance is measured again. The properties of the material, as well as the geometric parameters of the object are calculated on the basis of the obtained values determined at each of the control frequencies.

The basic advantage of the given method in comparison to the previous one in which a compensating probe is also employed is in the use of two control frequencies. This allows to perform measurements at various penetration depths of the eddy-current magnetic field into the material, and thus- to take into account, to a definite degree, the geometric parameters of the controlled object during the calculation of the material properties, for example, its electrical conductivity.

The main disadvantages of this method and of the eddy-current probe as regard their use in measuring the electrical conductivity of the polymer electrolyte films are:

inadequate number of the measurement frequencies precluding determination of the dependence between the introduced impedance of the measuring coil and the frequency;

absence of data on the material dielectric losses that does not allow to adjust the introduced impedance values at the measurement frequencies;

impossibility of determining the polymer film thickness with an adequate accuracy.

### SUMMARY OF THE INVENTION

The main purpose of the invention is to obtain valid results of measuring the specific electrical conductivity of polymer electrolytes.

The purpose is achieved by means of a method and an integral probe for non-contact measuring electrical conductivity of polymer electrolytic films comprised of placing the film on a flat dielectric substrate, exciting a probing vortex magnetic field by means of an inductance coil at a series of discrete frequencies and measuring its impedance at these frequencies with the operating face of the coil being placed on the film surface and on the substrate, placing a correcting probe inside of the coil according to the invention by determining at the first frequency of the operating range the active part of the impedance introduced into the coil related to the own reactive resistance of the coil, measuring the capacity and the Q-factor of the correcting capacitance probe, determining the relative value of the introduced reactive resistance of the coil, repeating these operations at each discrete frequency of the operating range, adjusting the relative values of the introduced active resistance, approximating the adjusted values within the operating frequency range, and extrapolating towards the lower frequencies, calculating the relationship between the extrapolated resistance value and the corresponding frequency using this value for determining the specific electrical conductivity of the polymer electrolyte caused by the movement of the free charge carriers.

The capacitance probe is comprised of two coplanar thin wafers whose outer surface is coincident with the outer surface plane of the edge turn in the induction coil.

Each of their capacitance probe wafers forms a sector of a circle that is arranged co-axially with the cylindrical induction coil. The circle radius does not exceed a half of the coil radius. The chords of the sectors are arranged parallel to each other and symmetrically relative to the coil center. The distance between the chords is at least five times higher of the maximum thickness of the electrolyte film samples.

The surfaces of the outer turn of the coil and of the capacitance probe wafers that contact the polymer electrolyte sample are coated with electrically high-quality wear resistant lacquer film whose thickness does not exceed 10 μm and is identical for the coil and wafers of the capacitance probe.

The dielectric penetrability of the electrolyte is determined at each discrete frequency of the operating range according to the capacitance probe capacity value in case the film substrate of the polymer electrolyte is metallic, taking into regard the thickness of the resilient polymer electrolyte loaded by the weight of the integral probe.

The coefficient value of dielectric losses is determined using the measured values of the dielectric penetrability and the Q-factor of the capacitance probe. The product of the dielectric loss coefficient by the frequency value is used for adjusting the relative active resistance introduced into the induction coil at each discrete frequency of the operating range.

The value of the relative reactive impedance introduced into the coil in case when the polymer electrolyte film is arranged in a metallic substrate is used to determine the thickness of the resilient polymer electrolyte loaded by the weight of the integral probe within the control spot of the inductance coil. The obtained is used for determining the dielectric penetrability and the specific electrical penetrability of the polymer electrolyte, repeating these operations at all discrete frequencies of the operating range.

The dielectric substrate is produced from a material with a tangent angle of dielectric losses not exceeding 10⁻⁴ within the range of metric wave lengths.

The metallic substrate is produced from a material with a specific electrical conductivity not less than 50 MCm/m.

The working surfaces of the dielectric and metallic substrates are formed with an identical and minimum possible roughness.

The relative introduced into the inductance coil active resistance is adjusted at each frequency by its multiplying by the coefficient equal to the difference relation of the mutual specific conductivity of the polymer and the product of the dielectric losses multiplied by the frequency, to the mutual specific conductivity. This operation is repeated at each discrete frequency within the range.

The mutual specific conductivity of the polymer electrolyte at each operating range frequency is determined from the frequency characteristic gradient of the relative introduced active resistance at the step preceding this frequency.

The adjusted values of the active resistances introduced into the inductance coil are approximated using a polynomial not exceeding the second degree using the least-squares technique. The obtained relationship is used for frequency extrapolation towards the lower frequencies. The per frequency number of extrapolation steps does not exceed 20% of the total operating frequency number within the frequency range being studied.

The inductance coil diameter is chosen within the 6 mm-20 mm range, while the minimum radial diameter of the sample should at leas 2 times exceed the coil diameter.

The minimum diameter of the coil winding wire is specified to be not less than one tenth of the coil diameter, but not above 1.5 mm. The specified coil turn number is not more than four.

The number of the coil turns, the diameter of the winding wire and the winding pitch are selected to correspond to the maximum sensitivity. In such case the own resonant frequency of the coil that is specified by its inductance and parasitic capacity values should be at least by an order higher of the upper frequency of the operating range.

The fittings used to fix to each other the wafers of the capacitance probe and the inductance coil are made of a dielectric with a tangent angle of electrical losses not exceeding 10⁻³. The total volume of the fittings is minimized according to the coil space factor.

The film thickness values measured at the discrete frequencies of the operating range are averaged, and the obtained value is used in calculating the specific electrical conductance of the polymer electrolyte according to the extrapolated value of the introduced active resistance of the inductance coil.

The dielectric substrate thickness is specified to be equal to the coil diameter, while the thickness of the metallic coil is specified to be not less than 3 mm.

### DESCRIPTION OF DRAWINGS

FIG. 1. Integrated probe on a polymer electrolyte film:

1—inductance coil, 2—capacitance probe wafers, 3—polymer electrolyte film, 4—substrate.

FIG. 2. Operating end face of the integrated probe:

1—outer turn of the inductance coil, 2—capacitance probe wafers.

FIG. 3. Circuit of capacitance transducer:

1—capacitance probe, 2—polymer electrolyte film, 3—metallic substrate, 4—wafers formed on metal surface.

FIG. 4. Dependence between the rated value A/s of the magnetic field vector potential of a turn in the free space and the relation z/R at ρ=R. Here R is the turn radius, ρ and z are coordinates in the cylindrical system of coordinates.

FIG. 5. Dependence between the rated value A/s of the magnetic field vector potential of a turn in the free space and the relation ρ/R at z/R=0. Here R is the turn radius, ρ and z are coordinates in the cylindrical system of coordinates.

FIG. 6. Dependence between the relative reactive resistance introduced into the inductance coil and the distance to the metallic substrate; coil radius R=4 mm, number of turns W=3.

FIG. 7. Dependence between the active resistance introduced into the impedance coil and the frequency for the electrolyte comprised of a basis polyvinilchloride polymer, LiClO₄ salt and propylen-carbonate plastifier. Salt concentration: 0. 5M; inductance coil radius R=4.4 mm, number of turns W=3.

### DETAILED DESCRIPTION OF THE INVENTION

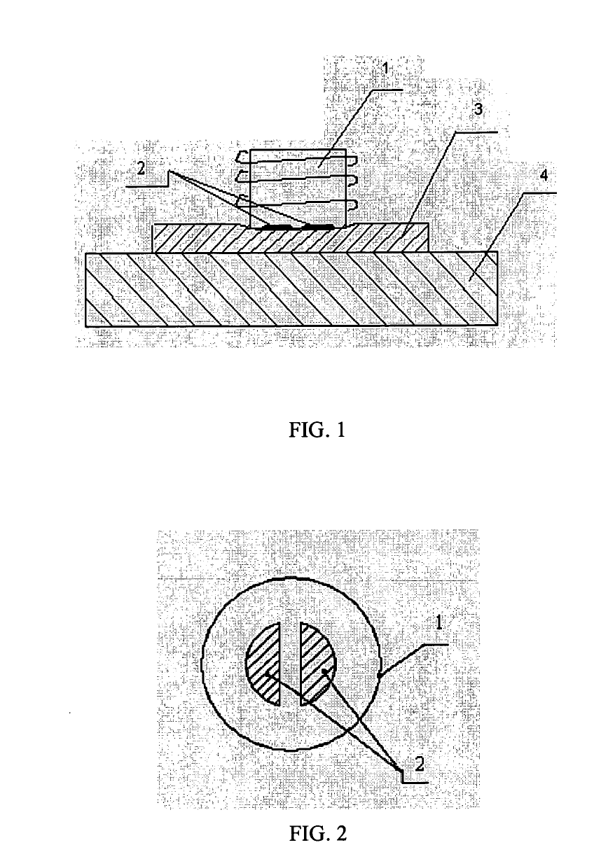

The inductance coil contains three turns (W=3) of copper wire of diameter d₀=1 mm. The coil outer diameter Dₒᵤₜ=9 mm, inner diameter Dᵢₙₙ=7 mm. Thus, the average diameter D=8 mm (radius R=4 mm). Inside of the coil a strap-type capacitance probe is arranged. The coil is placed on the surface of a polymer electrolyte film that is placed on a substrate (FIG. 1). The capacitance probe is made in the form of two copper 0.5 mm thick wafers each shaped as a sector of a circle (FIG. 2). The diameter of this circle is 4 mm. The chords of the wafer sectors are parallel to each other and symmetrical relative to the coil center. The distance between the chords is specified to be 1 mm. The surfaces of the outer turn of the coil and of the capacitance probe wafers contacting the sample are coated with a high-frequency enamel lacquer, such as polyvinylacetate lacquer (vinyflex). The lacquer film thickness is 8 μm.

Thus, between the metallic surface of the outer turn of the coil, the surface of the capacitance probe wafers and the surface of the polymer electrolyte sample a thin high Q-factor insulating film is inserted. Thus an ohmic contact is excluded between the metal of the turn and the wafers with the electrolyte, and the contact phenomena related thereto, and the measurements are thus made without any electrical contact.

A sinusoidal current of different frequency is passed through the turns of the coil, hence an eddy-current magnetic field of respective frequencies is excited within the space surrounding the coil. Initially, at the first frequency of the operating range, the coil is installed on the surface of the electrolyte film that is placed on the dielectric substrate made of a polytetrafluorethylene (PTFE). The film samples are of circular shape, their diameter was 17 mm. Thus the requirement is met to have the minimum radial size of the sample not less than two times exceeding the diameter of the coil. In such case the coil magnetic field practically does not get beyond the limits of the electrolyte film in the radial direction (see Example 1).

The magnetic field of the inductance coil induces in the electrolyte film an eddy current flowing along a closed circuit. In our case the maximum density of the eddy current is observed directly under the outer turn of the coil. In general the circuit diameter of the eddy current induced in a conducting medium is determined not only by the coil diameter, but is also a function of the relative distance (gap) between the surface of the outer turn and the outer surface of the medium. In our case the gap-to-coil radius ratio Δh/R=0.1 mm/4 mm=0.025, that is very small. Therefore the eddy-current circuit diameter is actually coincident with the coil diameter.

As a result of the eddy current appearing in the electrolyte film the own active resistance of the coil gets increased by a certain value that is designated as the introduced resistance.

The relative value of the introduced resistance is usually used in the calculations, that is the introduced resistance is rated relative to the own reactive impedance of the coil at the given frequency. The own reactive impedance of the coil is determined while the operating end face of the coil is placed directly on the substrate. As it was stated above, the substrate is comprised of PTFE that has no influence on the magnetic field of the coil and from this viewpoint is equivalent to air or to vacuum.

Experience shows that due to the low conductivity of the polymer electrolyte the reactive part of the introduced impedance caused by the influence of the magnetic field of the film eddy current on the inductance coil is practically zero.

After determining the active introduced resistance the dielectric substrate is replaced by a substrate from a non-magnetic metal. For example, in the experiments described below we used a 3 mm thick copper plate. In such case the capacity and the Q-factor of the correcting capacitance probe is determined.

When the electrolyte film was placed on the dielectric substrate the lines of force in the potential electric field wafers of the strap-type capacitor were concentrated not only on the film, but also caught a substantial part of the substrate area. Since the electric properties of the film and its thickness within the control spot differ from sample to sample, the relation of the electric field intensity values in the film and in the substrate also changes. Hence, the influence of the substrate does not remain constant.

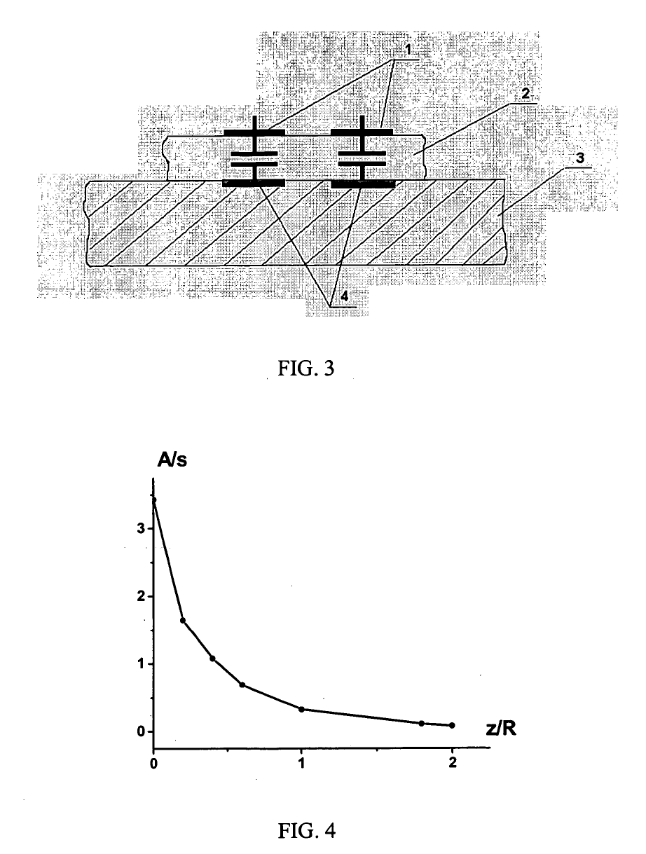

FIG. 3 shows a capacitance probe circuit in case the substrate is metallic. Opposite each wafer of the strap-type capacitor on the metallic substrate surface a corresponding quasi-plate is formed due to the concentration of the free charge carriers. Thus we obtain two series connected parallel-plate capacitors field with the polymer electrolyte being studied. At the first frequency of the operating range the total capacity and the Q-factor of the capacitance probe are measured. On the basis of the obtained values the capacity and the Q-factor of the formed parallel-plate capacitor are determined. Knowing the film thickness within the control area that is determined according to the introduced coil inductance, and the surface area of the wafers, the dielectric permeability of the polymer electrolyte is found.

Tangent of the angle of the material dielectric losses is determined as the ratio of the dielectric loss factor ε″ to the dielectric permeability ε′. The tangent value is inversely proportional to the Q-factor, that is tgδ=1/Q. Therefore, knowing the dielectric permeability ε′ and value tgδ it is possible to determine the dielectric loss coefficient value ε″=ε′ tgδ.

It is known that in the materials with low dielectric quality that are characterized both by the presence of the channel conductance and the presence of dielectric losses that appear during the shift and re-orientation of the bound charges in the outer field the electrical conductance is presented as the sum:
σ=σ₀+ωε₀ε″, (1)
where σ₀ is the channel conductance caused by the movement of the flee charge carriers; ω=2πf is the angular frequency, ε₀=8,8.10⁻¹² F/m is the dielectric constant of the vacuum; ε″ is the dielectric loss factor.

The polymer electrolytes also refer to the materials that are described by formula (1).

The mutual electrical conductivity σ (1) is measured within the high frequency range by means of an inductance coil (eddy-current probe). At the same time, in order to evaluate the quality of the electrolyte used in chemical power sources the channel conductance σ₀ is required that is caused by the movement of free charge carriers, primarily of the ions. Therefore at the first frequency of the operating range the product ωε₀ε″ is calculated to be used in adjusting the respective value of the relative active resistance introduced into the coil.

The described operations are repeated at each discrete frequency of measuring within the operating range. The value of the relative active resistance introduced into a single-turn coil for a thin polymer electrolyte film (to I mm thickness) can be presented in the form:

$$\frac{{R}_{BH}}{ω {L}_{0}} = \frac{72 * {10}^{- 7}}{{L}_{0}} \frac{{R}^{2} d ω σ {μ}_{0}}{9 + {( R d ω σ {μ}_{0} )}^{2}} , \qquad ( 2 )$$

where R_{BH}—is the active resistance introduced into the coil, L₀ is the own inductance of the coil, ω=2πf is the angular frequency, R is the coil radius, d—film thickness, σ—specific conductance of the polymer electrolyte, μ₀=4π* 10⁻⁷ Gn/m—magnetic constant in vacuum. Let us calculate the value of the second addend in the denominator (2) for R=4 mm, d=0.1 mm, ω=2π* 10⁸ Hz, σ=1 Cm/m.

Then Rdωσμ₀=0.315*10⁻³. It is obvious that the second addend in the denominator in comparison to 9 can be neglected.

In such case

$$\frac{R \hat{a} í}{ω {L}_{0}} = \frac{32 π * {10}^{- 14}}{{L}_{0}} {R}^{2} d ω σ \qquad ( 3 )$$

Let us determine the mutual specific conductance of the polymer electrolyte σ(1) according to the frequency characteristic gradient R_{BH}/ωL₀ at the step preceding the given frequency. Then the correction R_{BH}/ωL₀ shall be done at this frequency by multiplying the value R_{BH}/ωL₀ by the coefficient k:

$$k = \frac{{σ}_{0}}{σ} = \frac{σ - ω {ɛ}_{0} {ɛ}^{″}}{σ} \qquad ( 4 )$$

This operation is repeated at each measurement frequency within the operating range.

As it has been mentioned above, due to its low conductivity the polymer electrolyte film actually has no influence on the coil inductance, while both the active resistance and the coil inductance are substantially influenced by the distance from the operating face of the coil to the metallic substrate surface.

Let us see which coil parameter - either the active or the reactive resistance is more preferable for measuring the distance from the metallic substrate, or actually the thickness of the polymer film on the metallic substrate.

According to the general theory of the turn interaction with the harmonic current and the conducting non-magnetic medium with the increase of the product of the conductance by the frequency σω the introduced active resistance R_{BH}/ωL₀ increases starting from the zero value, passes through the maximum and then decreases to the zero value. With the increase of σω the introduced reactive resistance monotonously increases. The maximum R_{BH}/ωL₀ is observed when the value of the generalized parameter β=R\sqrt{ωσμ₀} approximately equals 5. As it follows from the data of work (see FIG. 3.1) at β=30 the value R_{BH}/ωL₀ is about 56% of the maximum value, at β=80-27%, at β=100-16%. In our case at R=4 mm, ω=2π*10⁸Hz, σ=5,6*10⁷ Cm/m (copper) the generalized parameter value β=841. In such case the value R_{BH}/ωL₀ is quite small and can be compared to the values obtained due to the influence of the electrolyte (useful signal). And since σ of the film change due to the concentration change of the salt and due to the influence of a number of other reasons, it is unreasonable to use the introduced active resistance for measuring the film thickness.

The introduced reactive resistance or the introduced inductance at β=841 is quite significant, and according to the same data of the work, (FIG. 3.1) the relation ωL/ωL₀ reaches 0.45, that is L_{BH}/L₀=0.55. This relation depends on the distance Δh between the plane of the coil turn and the metallic substrate surface. For the coil with the number of turns W=3 the mechanism of forming a dependence between the distance and the metallic substrate is discussed in Example 3, while the respective dependence is shown in FIG. 6.

The polymer film thickness measuring at the location of the operating end face of the integrated probe is necessary for a number of reasons. First, experience shows that it is rather problematic to obtain films with a uniform thickness even within a 2-3 cm² area; second, a polymer electrolyte film is resilient, and when an integrated transducer is installed thereon, under the load of the latter, though it is not heavy, the film thickness changes; third, in the process of drying out the film thickness and its resilience properties change; fourth, as a high uniformity of the film is not always achieved, the use of optical methods of determining its thickness, at least at the faces, features substantial errors.

The film thickness value measured according to the value of the reactive resistance introduced into the coil is used for determining the dielectric penetrability and the specific electrical conductance of the polymer electrolyte at all discrete frequencies of the operating range.

The obtained values of the relative introduced into the inductance coil active resistances adjusted by the signals of the capacitance transducer, are approximated by a polynomial dependence. The numerous studies on samples of liquid and polymer electrolytes with salts LiCF₃SO₃, LiClO₄, LiN(CF₃SO₂)₂, of various concentration values, and coils of different diameters with the number of turns W=1,2,3,4 (when W>4 the measurement sensitivity deteriorates) have shown that the relationships between R_{BH}/ωL₀ and the frequency are best of all approximated (with a minimum root-mean-square deviation) either by a linear or a parabolic type dependence.

A linear type dependence in the majority of cases indicates the stability of conductance σ within the frequency range being studied, while a parabolic type dependence indicates with a high degree of probability on the presence of dielectric losses in the polymer electrolyte. Besides, in some cases there may also exist a dependence of the channel conductance σ₀ on the frequency caused, for example, either by a change of the concentration of charge carriers or of their mobility.

As a rule, at frequency dependencies the spread of points is not large, and the correlation coefficient exceeds 0.9 in most cases. This permits to extrapolate even when 6 measuring points are available, by using an approximating dependence, one step to the left towards the lower frequencies. For maintaining a rather high validity of the results the number of the extrapolation steps should not exceed 20% of the number of operating frequencies within the operating frequency range being studied.

Thus, for example, with a coil of W=3 frequencies 40, 50, 60, 70, 80, 90, 100 MHz were used (see Example 6). Extrapolation was performed for the 30 MHz frequency.

A study of parametric eddy-current probes in the form of short cylindrically shaped inductance coils (solenoids) has shown that within the coil diameter range of 6-20 mm with a tightly wound wire of a diameter from one tenth of the coil diameter to 1.5 mm the maximum sensitivity is achieved with the number of coils W=3-4. While producing a coil it should be taken into consideration the value of the own resonant coil frequency that is determined by its inductance and the parasitic intercoil capacitance. To exclude any additional errors related to the influence of resonant phenomena during the measurements the own resonant frequency of the coil should be not less than by an order higher of the upper frequency value of the operating frequency. A reduction of the own resonant frequency is achieved by reducing the number of the coil turns W and by increasing the distance between the turns.

When the field frequency of the induction coil equals zero (ω=0) the eddy currents are not induced in the conducting medium, and the introduced impedance of the coil equals zero. Thus, at the frequency characteristic R_{BH}/ωL₀ the extrapolated value R_{BH}/ωL₀ can be connected by a line segment with the point where the coordinates begin. The inclination of this line to the abscissa axis or, in other words, the relation of the extrapolated value R_{BH}/ωL₀ to the frequency corresponding thereto will give the value, according to which, using the expressions (3) for W=1 or a more complicated procedure (see Example 4) the specific conductance of the polymer electrolyte is determined that is caused by the movement of the free charge carriers.

The following examples further illustrate the present invention.

### EXAMPLE 1

The magnetic field vector potential of a turn with a harmonically changing current within a free space in case when the center of the cylindrical system of coordinates is placed in the turn center can be presented in the form:

$$A = \frac{{μ}_{0} IR}{2} {\int }_{0}^{∞} {J}_{1} ( λ R ) {I}_{1} ( λ ρ ) {ⅇ}^{- λ \vert Z \vert} ⅆ λ , \qquad ( 5 )$$

where I is the current in the turn, R—turn radius, μ₀=4π.10⁻⁷ΓH/M—magnetic constant, J₁—Bessel's function of the first order, λ—conversion parameter; ρ,z—coordinates of the cylindrical system of coordinates. The integral in (5) is expressed through the full elliptical integrals of the first E and the second K type, whose tables are contained in a number of mathematical reference books including:

$$\begin{matrix}A = \frac{{μ}_{0} I}{π k} \sqrt{\frac{R}{ρ} [ ( 1 - \frac{{k}^{2}}{2} ) K ( k ) - E ( k ) ] ,} & ( 6 ) \\ Where {k}^{2} = \frac{4 R ρ}{{( R + ρ )}^{2} + {z}^{2}} . & \end{matrix}$$

The electrical field intensity is directed along the coordinate φ of the cylindrical system f coordinates and is proportional to the vector potential of the magnetic field. The EMF induced by the magnetic field of the turn in any circuit co-axial thereof and equal to the vector E circulation through this circuit, is also proportional to the vector potential. Thus, value A is an effective characteristic of the turn field, and, respectively, of a low-turn measuring coil. FIG. 4 illustrates the calculated according to formula (6) dependence of the value A/s, where s=μ₀I/π=const, on the relation z/R at ρ=R. As it follows from the graph at z/R₁=1 the vector potential value is reduced approximately by 10 times of the maximum value observed at z-0, while at z/R=2 the vector potential value is reduced approximately by 40 times, that is approximately equals 2.5% of the maximum value. The same situation approximately exists when a low-turn coil is used.

Thus, it may be considered that if the distance between the face of the measuring coil and die border of the conducting medium equals two radii and more of the coil then the medium actually has no influence on the coil impedance.

### EXAMPLE 2

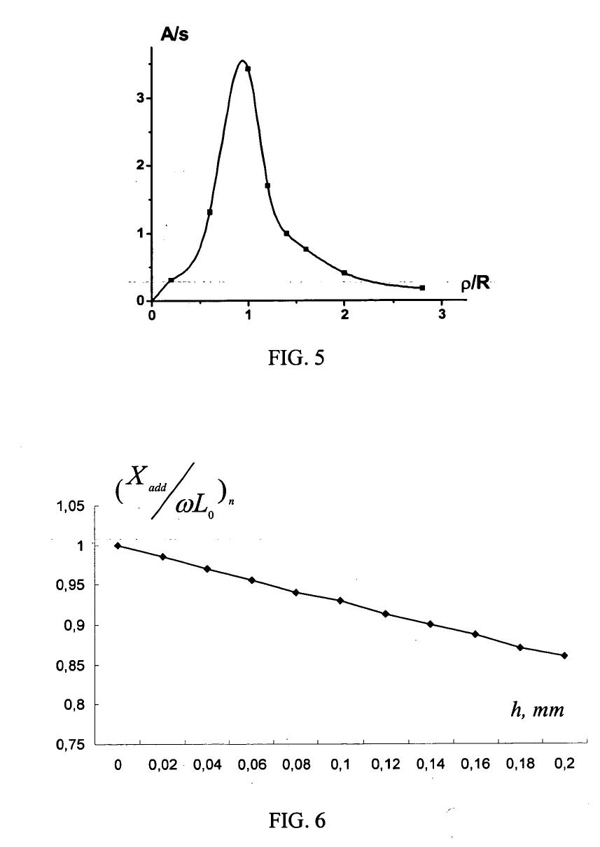

The results of calculating the vector potential A/s as a function of the radial coordinate ρ/R at z/R=0 according to the formula (6) given in Example 1, are shown in FIG. 5. The graph is plotted for the field in a free space.

The graph shows that at a distance from the turn center ρ/R=2 the value A/s is approximately 12% of the maximum value. Approximately the same situation is also maintained for a low turn coil. In a conducting medium the field damps faster than in a free space. In such case the damping rate along the radial coordinate gets increased with an increase of the product of the field frequency on the material conductance. Hence, if the diameter of the polymer electrolyte film is twice higher of the measuring coil diameter, then on the outer radial border of the sample the value of the field vector potential is less than 10% of the maximum value, and such an error is admissible during the practical use of the method.

### EXAMPLE 3

To study the dependence of the relative introduced into the coil reactive impedance X_{BH}/ωL₀ on the distance from the edge turn to the copper plate surface h there was used a coil of diameter D=8 mm, densely coiled with wire d₀=1 mm, number of turns W=3. A corresponding experimentally derived dependence is shown in FIG. 6. The dependence is rated against the maximum value achieved at h=0. The graph shows that within the polymer electrolyte thickness range to 0.2 mm (in the majority of cases the film thickness is within this range) the dependence is practically linear and is characterized by a sensitivity that is acceptable for practical usage.

### EXAMPLE 4

The expression (3) is used in calculating the specific conductance σ for a single-turn coil (W=1) with a gap h=0. Let us discuss the procedure for determining the specific conductance at W>1.

Let W=2 and the gap between the edge turn of the coil and the surface of the material is still negligibly small in comparison to the coil radius. Then due to the fact that the second coil turn is found at a distance from the material surface equal to the wire diameter of the first turn d₀ (dense winding) factor P appears in the expression (3) characterizing the influence of the generalized gap for the whole coil

$$P = {ⅇ}^{\frac{- 3 {h}_{1}}{R}} + {ⅇ}^{\frac{- 3 ( {h}_{1} + {h}_{2} )}{2 R}} + {ⅇ}^{\frac{- 3 ( {h}_{2} + {h}_{1} )}{2 R}} + {ⅇ}^{\frac{- 3 {h}_{2}}{R}} \qquad ( 7 )$$

where h₁ is the gap between the first turn of the coil and the surface of the material, h₂—the gap between the second turn of the coil and the surface of the material.

If h₁=0, and h₂=d₀, then

$$P = {ⅇ}^{\frac{- 3 {d}_{0}}{R}} + 2 {ⅇ}^{\frac{- 3 {d}_{0}}{2 R}} \qquad ( 8 )$$

Factor P describes the interaction of the coil turns through the conducting medium. Thus, in the expression (7) the first addend corresponds to the process of exciting by the field of the first turn of an eddy current trajectory in the medium and of the interaction between the field of this eddy current and the first turn. The second addend corresponds to the process of interaction of the eddy current field excited by the first turn with the second turn. The third addend corresponds to the process of interaction between the eddy current field excited by the second turn, and the first turn. The fourth addend corresponds to the process of interaction between the eddy current field excited by the second turn, and the second turn.

At W=3 the expression for P has the following form:

$$P = {ⅇ}^{\frac{- 3 {h}_{1}}{R}} + {ⅇ}^{\frac{- 3 {h}_{2}}{R}} + {ⅇ}^{\frac{- 3 {h}_{3}}{R}} + 2 {ⅇ}^{\frac{- 3 ( {h}_{1} + {h}_{2} )}{2 R}} + 2 {ⅇ}^{\frac{- 3 ( {h}_{1} + {h}_{3} )}{2 R}} + 2 {ⅇ}^{\frac{- 3 ( {h}_{2} + {h}_{3} )}{2 R}} \qquad ( 9 )$$

where h₁, h₂, h₃—the distance from the corresponding turns to the surface of the conducting medium.

Besides the interaction of the coil turns through the conducting medium they interact between one another due to the mechanism of mutual induction thus redistributing the resistances introduced into each turn. Hence, the active resistance R_{GH}⁽¹⁾ introduced into the first turn, due to the mutual induction of the turns M leads to the appearance in the second turn of the introduced resistance R_{GH}⁽¹²⁾:

$${R}_{βH}^{( 12 )} = \frac{{( ω M )}^{2} {R}_{βH}^{( 1 )}}{{ω}^{2} {L}_{0}^{2} + {( {r}_{0} + {R}_{βH}^{( 1 )} )}^{2}} , \qquad ( 10 )$$

where L₀ and r₀—the own inductance and the active resistance of the turn

If the Q-factor of the turn placed on the electrolyte film surface is Q₁=ωL₀/(r₀+R_{GH}⁽¹⁾>>1, and this is always fulfilled in our experiments where it is seldom below 100 due to the relatively low conductance values of the polymer electrolyte and of the film thickness, then the square Q₁ is obviously >>1, hence, the second component in the denominator (10) can be neglected.

$${R}_{βH}^{( 12 )} = {( \frac{M}{{L}_{0}} )}^{2} {R}_{β H}^{( 1 )} . \qquad ( 11 )$$

The inductance of the turn is determined through the expression:

$${L}_{0} = {μ}_{0} R ( L n \frac{8 D}{{d}_{0}} - \frac{7}{4} ) , \qquad ( 12 )$$

where D is the diameter of the coil turn, d₀—wire diameter. The mutual inductance of two co-axial turns is determined through the expression:

$$M = \frac{{µ}_{0}}{4 π} RF ( S / 2 R ) , \qquad ( 13 )$$

where S is the distance between the axial lines of the wires in the adjacent turns, function F equals:

$$F ( λ = S / 2 R ) = 4 π [ ( 1 + \frac{3}{4} {λ}^{2} - \frac{16}{64} {λ}^{4} + \frac{35}{256} {λ}^{6} + … ) ln \frac{4}{λ} - 2 - \frac{1}{4} {λ}^{2} + \frac{31}{128} {λ}^{4} - \frac{247}{1536} {λ}^{6} + … ] . \qquad ( 14 )$$

Let us discuss an example of a concrete calculation of the introduced active resistance of a two-turn coil in accordance with the described mechanism. Parameters of the coils: R=4 mm, d₀=1 mm. Then

$${R}_{6 H}^{( 1 )} = {R}_{6 H0} [ 1 + {ⅇ}^{\frac{- 3}{4} ( \frac{0 , 5 + 1 , 5}{2} )} ] = 1 \text{,} 47 {R}_{6 H0} , \qquad ( 15 )$$

where R_{GH0} is the resistance introduced into the first turn, 0.5 mm is the distance from the axis of the first turn to the film surface, 1.55 mm is the distance from the axis of the second turn to the electrolyte film surface.

The introduced resistance of the second turn

$${R}_{6 H}^{( 2 )} = {R}_{6 H0} [ {ⅇ}^{\frac{3}{4} 1 , 5} + {ⅇ}^{\frac{3}{4} \frac{( 1 , 5 + 0 , 5 )}{2}} ] = 0 \text{,} 79 {R}_{6 H0} . \qquad ( 16 )$$

Thus, without taking into regard the mechanism of mutual inductance the introduced resistance of a two-turn coil equals
R_{GH}(W=2)=R_{GH}⁽¹⁾+R_{GH}⁽²⁾=2,26R_{GH0}. (17)

The relation M/L₀ taking into regard (11), (12) equals:

$$\frac{M}{{L}_{0}} = \frac{F ( S / 2 R )}{4 π ln ( \frac{8 D}{{d}_{0}} - \frac{7}{4} )} . \qquad ( 18 )$$

In our case M/L₀=0.62.
Then
   R_{BH}(W=2)=2,26R_{BH0}+0,38R_{BH}⁽¹⁾0,38R_{BH}⁽²⁾2,26R_{BH0}+0,86R_{BH0}=3,12R_{BH0}. (19)
   Here (19) value 0.86R_{BH0} in the last sum is actually provided by the mechanism of self-induction.
The described mechanism is taken into regard in the calculation of the electrolyte specific conductance.

### EXAMPLE 5

Let us calculate the magnetic field of a round turn under current as a function of the cylindrical coordinate ρ(ρ=0 in the center of the turn). In accordance with the intensity components of the magnetic field H in the cylindrical system of coordinates in the turn plane (z=0) are determined through formulas

TABLE 1

| H_{z}/I | ρ ,mm |
|---|---|
| 0.0625 | 0 |
| 0.0658 | 1 |
| 0.0763 | 2 |
| 0.114 | 3 |

$${H}_{α} = 0 , {H}_{ρ} = 0 , {H}_{z} = \frac{I}{2 π} [ \frac{K ( {k}^{2} )}{( R + ρ )} + \frac{N ( {k}^{2} )}{( R - ρ )} ] , \qquad ( 20 )$$

where R is the turn radius, I—current amplitude in the turn, K and N—complete elliptical integrals of the first and the second order. Using series of integrals K and N the normal component of the field H_{z} was calculated as a function of the coordinate ρ, with the help of the intermediate parameter k²=4ρR/.

The calculation results for R=4 mm are given in Table 1. By limiting the radius of the circle that includes sectors (wafers) of the capacitance probe to the value of 2 mm we shall arrange the wafers within the area of a relatively weak field. The capacity of the capacitance transducer when the dielectric permeability of the polymer electrolyte ε′=10 and the thickness of the film placed on a metallic substrate d=0.1 mm equals 2.3 pF for such a capacitance probe. It is quite enough for the provision of a measuring circuit.

### EXAMPLE 6

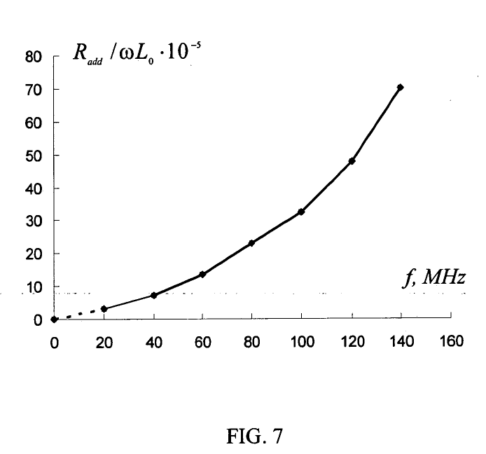

Let us discuss the adjusted for the dielectric losses dependence of the value R_{BH}/ωL₀ on the frequency for the polymer electrolyte film with salt LiClO₄, the salt concentration is 0.1 M. An inductance coil was used of radius R=4.4 mm, wire diameter d_{0 =1} mm, number of turns W=3. The measurements were carried out at frequencies f=40, 60, 80, 100, 120, 140, MHz. The corresponding dependence R_{BH}/ωL₀ on the frequency f is shown in FIG. 7. The value R_{BH}/ωL₀ extrapolated by the second degree polynomial for the 20 MHz frequency equals 2,98*10⁻⁵. The transition to the extrapolated value from the 40 MHz to 20 MHz frequency is shown on the graph by a thin continuous line, while the section of the frequency characteristic on which the specific conductance of the polymer electrolyte was calculated is shown by a dashed line. The calculated value of the specific conductance σ₀=2.2 Cm/m. The calculation was performed according to the expression (3) using the methodology described in Example (4).

References

U.S. Pat. No. 4,303,885, Dec. 01, 1981, Davis et. al., G 01 N 027/82, G 01 R 33/12
U.S. Pat. No. 5,889,401, Mar. 30, 1999, Jourdain et. al., G 01 N 027/72, G 01 R 33/12
U.S. Pat. No. 6,288,536, Sep. 11, 2001, Mandl et. al., G 01 N 027/72, G 01 R 33/12
U.S. Pat. No. 6,479,990, Nov. 12, 2002, Mednikov et. al., G 01 N 027/72, G 01 R 33/00
U.S. Pat. No. 6,593,738, Jul. 15, 2003, Kesil et. al., G 01 N 027/72.
   1. Hippel A. R., Dielectric and Waves, New York, 1954.
2. Matiss I. Capacitance probes for nondestructive testing. Riga, Publishing House “Zinatne”, 1982.
3. Sobolev V. S., Shkarlet Yu. M., Strap and screen type probes, Novosibirsk, Nauka Publishers, 1967.
4. Levy S. Electromagnetic shielding effect of an infinite plane conducting sheet placed between circular coaxial coils. Proc. IRE,1936, 24, N 6.
5. Kalantarov P. L., Tseitlin L. A., Calculation of inductances. Leningrad, Energoatomizdat Publishers, 1986.
6. Smythe W. R. Static and Dynamic Electricity. New York, 1939.
7. Stratton J. A. Electromagnetic Theory, New York, 1941.

1. Method for non-contact measuring electrical conductivity of polymer electrolytic films by means of an integrated probe comprised of placing the film on a flat dielectric substrate, exciting a probing vortex probing magnetic field by means of an inductance coil at a series of discrete frequencies and measuring its impedance at these frequencies with the operating face of the coil being placed on the film surface, and then on the substrate, placing a correcting probe inside of the coil, wherein at the first frequency of the operating range the active part is determined of the impedance introduced into the coil related to the own reactive resistance of the coil, the dielectric substrate is replaced with a substrate from a non-magnetic metal, while measuring the capacity and the Q-factor of the correcting capacitance probe, determining the relative value of the introduced reactive resistance of the coil, repeating these operations at each discrete frequency of the operating range, adjusting the relative values of the introduced active resistance, approximating the adjusted values within the operating frequency range, and extrapolating towards the lower frequencies, calculating the relationship between the extrapolated resistance value and the corresponding frequency using this value for determining the specific electrical conductivity of the polymer electrolyte caused by the movement of the free charge carriers.

2. Method according to claim 1, wherein the capacitance probe is comprised of two coplanar thin wafers whose outer surface is coincident with the outer surface plane of the edge turn in the induction coil.

3. Method according to claim 1, wherein each of the capacitance probe wafers forms a sector of a circle that is arranged co-axially with the cylindrical induction coil, while the circle radius does not exceed a half of the coil radius, the chords of the sectors are arranged parallel to each other and symmetrically relative to the coil center, the distance between the chords being at least five times higher of the maximum thickness of the electrolyte film samples.

4. Method according to claim 1, wherein the surfaces of the outer turn of the coil and of the capacitance probe wafers that contact the polymer electrolyte sample are coated with electrically high-quality wear resistant film whose thickness does not exceed 10 μm and is identical for the coil and wafers of the capacitance probe.

5. Method according to claim 1, wherein the dielectric penetrability of the electrolyte is determined at each discrete frequency of the operating range according to the capacitance probe capacity value in case the film substrate of the polymer electrolyte is metallic, taking into regard the thickness of the resilient polymer electrolyte loaded by the weight of the integral probe.

6. Method according to claim 1, wherein the coefficient value of dielectric losses is determined using the measured values of the dielectric penetrability and the Q-factor of the capacitance probe while the product of the dielectric loss coefficient by the frequency value is used for adjusting the relative active resistance introduced into the induction coil at each discrete frequency of the operating range.

7. Method according to claim 1, wherein the value of the relative reactive impedance introduced into the coil in case when the polymer electrolyte film is arranged in a metallic substrate is used to determine the thickness of the resilient polymer electrolyte loaded by the weight of the integral probe within the control spot of the inductance coil while the obtained is used for determining the dielectric penetrability and the specific electrical penetrability of the polymer electrolyte, these operations being repeated at all discrete frequencies of the operating range.

8. Method according to claim 1, wherein the dielectric substrate is produced from a material with a tangent angle of dielectric losses not exceeding 10⁻⁴ within the range of metric wave lengths.

9. Method according to claim 1, wherein the metallic substrate is produced from a material with a specific electrical conductivity not less than 50 MCm/m.

10. Method according to claim 1, wherein the working surfaces of the dielectric and metallic substrates are formed with an identical and minimum possible roughness.

11. Method according to claim 1, wherein the relative introduced into the inductance coil active resistance is adjusted at each frequency by its multiplying by the coefficient equal to the difference relation of the mutual specific conductivity of the polymer and the product per p. 6 of the dielectric losses multiplied by the frequency, to the mutual specific conductivity, this operation being repeated at each discrete frequency within the range.

12. Method according to claim 1, wherein the mutual specific conductivity of the polymer electrolyte at each operating range frequency is determined from the frequency characteristic gradient of the relative introduced active resistance at the step preceding this frequency.

13. Method according to claim 1, wherein the adjusted values of the active resistances introduced into the inductance coil are approximated using a polynomial not exceeding the second degree using the least-squares technique, with the obtained relationship being used for frequency extrapolation towards the lower frequencies, while the per frequency number of extrapolation steps does not exceed 20% of the total equidistant operating frequency number within the frequency range being studied.

14. Method according to claim 1, wherein the inductance coil diameter is chosen within the 6 mm-20 mm range, while the minimum radial diameter of the sample should at least 2 times exceed the coil diameter.

15. Method according to claim 1, wherein the minimum diameter of the coil winding wire is specified to be not less than one tenth of the coil diameter, but not above 1.5 mm, while the specified coil turn number is not more than four.

16. Method according to claim 1, wherein the number of the coil turns, the diameter of the winding wire and the winding pitch are selected to correspond to the maximum sensitivity to the introduced active resistance, while the own resonant frequency of the coil that is specified by its inductance and parasitic capacity values should be at least by an order higher of the upper frequency of the operating range.

17. Method according to claim 1, wherein the fittings used to fix to each other the wafers of the capacitance probe and the inductance coil are made of a dielectric with a tangent angle of electrical losses not exceeding 10⁻³, while the total volume of the fittings is minimized according to the coil space factor.

18. Method according to claim 1, wherein the film thickness values measured at the discrete frequencies of the operating range are averaged, and the obtained value is used in calculating the specific electrical conductance of the polymer electrolyte according to the extrapolated value of the introduced active resistance of the inductance coil.

19. Method according to claim 1, wherein the dielectric substrate thickness is specified to be equal to the coil diameter, while the thickness of the metallic coil is specified to be not less than 3 mm.
